(19) United States
(12) Patent Application Publication
(10) Pub. No.: US 2017/0257146 A1
(43) Pub. Date: Sep. 7, 2017

(54) FACILITATING ALIGNMENT OF WIRELESS ELEMENTS FOR ULTRA SHORT RANGE WIRELESS INTERACTION

(71) Applicant: Nanoport Technology Inc., Markham (CA)

(72) Inventor: Timothy Jing Yin Szeto, Markham (CA)

(73) Assignee: Nanoport Technology Inc., Markham (CA)

(21) Appl. No.: 15/282,907

(22) Filed: Sep. 30, 2016

Related U.S. Application Data
(60) Provisional application No. 62/302,094, filed on Mar. 1, 2016.
(60) Provisional application No. 62/348,690, filed on Jun. 10, 2016.

(51) Int. Cl. H04B 5/00; H05K 5/02; H02J 50/10; H04W 4/00

(52) U.S. Cl. CPC H04B 5/0075; H04W 4/008; H04B 5/0037; H05K 5/0226; H02J 50/10

(57) ABSTRACT

In an embodiment, an electronic device may comprise a wireless element and a pair of magnetic connectors. The magnetic connectors may be spaced apart from one another and may be in fixed relation to the wireless element. The pair of magnetic connectors may be configured to self-align with, and interconnect with, a complementary pair of magnetic connectors of another electronic device and to thereby align the wireless element with a complementary wireless element of the other electronic device for ultra short range wireless interaction between the electronic devices via the aligned wireless elements. The wireless elements may for example be antennas, coils, or electric induction couplers. The wireless interaction may for example be wireless communication or wireless power transfer. The magnetic connectors may incorporate cylindrical magnets. In an embodiment, the electronic device may have only one magnetic connector.

### CROSS-REFERENCE TO RELATED APPLICATIONS

The present application claims the benefit of prior U.S. provisional application Ser. No. 62/302,094 filed Mar. 1, 2016 and prior U.S. provisional application Ser. No. 62/348,690 filed Jun. 10, 2016, the contents of both of which are hereby incorporated by reference hereinto.

### TECHNICAL FIELD

The present disclosure relates to facilitating alignment of wireless elements, such as antennas, coils, or electric induction couplers, for ultra short range wireless interaction.

### BACKGROUND

An electronic device, such as a mobile phone (e.g. smartphone), digital watch (e.g. smartwatch), tablet computer, laptop computer, or the like, may wirelessly interact with another electronic device of the same type or of a different type. Each of the devices may incorporate one or more wireless elements for effecting the wireless interaction.

In one example, the wireless interaction may be wireless communication, and the wireless elements may be antennas. The wireless communication may for example conform to an established wireless communication protocol, such as Wi-Fi™, Bluetooth™ or near-field communication (NFC). Each electronic device may have a transmit antenna for transmitting outgoing wireless signals and a receive antenna for receiving incoming wireless signals. The transmit antenna may for example be an omnidirectional antenna that emits radiation substantially equally in all directions in a spherical radiation pattern, or another omnidirectional antenna that radiates radio wave power in a torus or “doughnut-shaped” radiation pattern (i.e. uniformly in all directions in a single plane but with the radiated power decreasing with elevation angle above or below the plane and dropping to zero on the antenna's axis). Other antenna types may be used.

The effective range of a wireless signal sent by a transmit antenna may depend upon a variety of factors, such as signal power and antenna type. When a receive antenna of one electronic device is outside the effective range of the transmit antenna of another electronic device, reliable wireless communication between the two may be difficult or impossible.

Ultra short range wireless communication is wireless communication that occurs at relatively short distances between transmit and receive antennas. In this document, ultra short range refers to distances of a few millimeters to a few centimeters between corresponding transmit and receive antennas. One example of ultra short range wireless communication is the use of NFC in a retail context to establish a wireless connection between a point-of-sale terminal and a portable electronic device, e.g. a smartphone, that is held proximate to the terminal, for the purpose of completing a purchase transaction.

In another example, the wireless interaction between devices may be wireless power transfer, e.g. for battery charging, and the wireless element may be induction coils. The wireless power transfer may for example be performed according to the Qi™ inductive power standard. During power transfer, a transmit induction coil of one device may be held or placed proximate to a receive induction coil of another device, with the distance between them being in the ultra short range.

### SUMMARY

According to one aspect of the present disclosure, there is provided an electronic device comprising: a wireless element; a pair of magnetic connectors spaced apart from one another and in fixed relation to the wireless element, the pair of magnetic connectors being configured to self-align with, and interconnect with, a complementary pair of magnetic connectors of an other electronic device and to thereby align the wireless element with a complementary wireless element of the other electronic device for ultra short range wireless interaction between the electronic devices via the aligned wireless elements.

Some embodiments further comprise a housing having an edge, wherein the pair of magnetic connectors and the wireless element are disposed along the edge of the housing.

In some embodiments, the wireless element is disposed between the pair of magnetic connectors at the edge of the housing.

In some embodiments, the edge is a straight rounded edge.

In some embodiments, the pair of magnetic connectors is configured to cause the straight rounded edge of the electronic device to physically connect with an edge of the other electronic device upon interconnection of the pairs of magnetic connectors, the other electronic device being pivotable about the straight rounded edge, in a hinge-like manner, without breaking the physical connection between the edges of the electronic devices, the wireless element being configured to remain aligned with the complementary wireless element of the other electronic device for ultra short range wireless interaction regardless of a current pivot position of the other electronic device about the straight rounded edge.

In some embodiments, the wireless element is a first wireless element, the pair of magnetic connectors is a first pair of magnetic connectors, and the electronic device further comprises a second wireless element in fixed relation to a second pair of magnetic connectors, the second pair of magnetic connectors configured to connect with a complementary second pair of magnetic connectors in the other electronic device when the other electronic device has been pivoted about the straight rounded edge into a face-to-face or back to back arrangement of the electronic devices, so as to provide a stable physical connection between the electronic devices in which the second wireless element is aligned with a complementary second wireless element in the other electronic device for ultra short range wireless interaction therebetween.

In some embodiments, the second wireless element and the additional magnetic connector is disposed along an opposing edge of the housing.

In some embodiments, the wireless element is a transmit antenna operable to produce an ultra short range wireless signal having a radiation pattern with an axis of radial symmetry that is substantially parallel to the straight rounded edge about which the other electronic device is pivotable.

Some embodiments further comprise an attachment surface to which the other electronic device is stably attachable using the pair of magnetic connectors, wherein the wireless element is situated on, beneath or behind the attachment surface.

In some embodiments, the transmit antenna is an omnidirectional antenna having a spherical radiation pattern.

In some embodiments, the transmit antenna is an omnidirectional antenna having a torus radiation pattern.

In some embodiments, the wireless element is a longitudinal electric induction coupler.

In some embodiments, the wireless element is a coil for effecting wireless power transfer.

In some embodiments, the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 5 millimeters.

In some embodiments, the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 10 millimeters.

In some embodiments, the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 30 millimeters.

In some embodiments, wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 50 millimeters.

In another aspect of the present disclosure, there is provided a method of facilitating ultra short range wireless interaction between two electronic devices, the method comprising: bringing a first electronic device into proximity with a second electronic device until a spaced apart pair of magnetic connectors in the first electronic device self-aligns and interconnects with a spaced apart pair of magnetic connectors in the second electronic device, the self-alignment and interconnection of the pairs of magnetic connectors automatically causing a wireless element in the first electronic device and a complementary wireless element in the second electronic device to align for ultra short range wireless interaction; and effecting the ultra short range wireless interaction between the wireless element of the first electronic device and the aligned complementary wireless element of the second device.

In some embodiments, the interconnecting of the pairs of magnetic connectors establishes a hinge-like physical interconnection of the two electronic devices that permits pivoting of one of the electronic devices relative to the other while maintaining the alignment of the wireless element and the complementary wireless element for ultra short range wireless interaction.

In some embodiments, each of the two electronic devices has an edge within which one of the pairs of magnetic connectors is disposed and wherein the interconnecting of the pairs of magnetic connectors longitudinally and axially aligns the edges of the electronic devices.

In another aspect of the present disclosure, there is provided an electronic device comprising: a wireless element; a magnetic connector in fixed relation to the wireless element, the magnetic connector being configured to self-align with, and interconnect with, a complementary magnetic connector of an other electronic device and to thereby align the wireless element with a complementary wireless element of the other electronic device for ultra short range wireless interaction between the electronic devices via the aligned wireless elements.

In a further aspect of the present disclosure, there is provided an electronic device comprising: a plurality of wireless elements; and a plurality of magnetic connectors in fixed relation to the wireless elements, the magnetic connectors being configured to self-align with, and interconnect with, complementary magnetic connectors of an other electronic device to physically interconnect the electronic device with the other electronic device in any one of a plurality of stable relative positions of the electronic devices, wherein the number of wireless elements that align with complementary wireless elements in the other electronic device for ultra short range wireless interaction is specific to the relative position of the electronic devices.

Other features will become apparent from the drawings in conjunction with the following description.

### BRIEF DESCRIPTION OF THE DRAWINGS

In the figures which illustrate example embodiments:

FIG. 1 is a perspective view of a system for ultra short range wireless communication comprising two electronic devices having magnetic connectors;

FIGS. 2 and 3 are perspective views of different types of magnets that may be used in the magnetic connectors of the electronic devices of the system of FIG. 1;

FIG. 4 is a perspective view of two complementary diametric cylindrical magnets that may form part of two complementary magnetic connectors, respectively, in the system of FIG. 1;

FIG. 5 is a perspective view of two complementary axial cylindrical magnets that may form part of two complementary magnetic connectors, respectively, in the system of FIG. 1;

FIGS. 6, 7 and 8 are front, side and cross-sectional views, respectively, of one of the electronic devices of FIG. 1 showing an example radiation pattern of an ultra short range wireless signal transmitted by an antenna within the electronic device;

FIGS. 9 and 10 are perspective and bottom views, respectively, of the two electronic devices of the system of FIG. 1 physically interconnected to one another, using magnetic connectors, so that complementary antennas in the respective devices are automatically aligned for ultra short range wireless communication;

FIGS. 11 and 12 are bottom views of the interconnected electronic devices of FIGS. 9 and 10 in different relative orientations in which ultra short range wireless communication between the devices can occur;

FIG. 13 is a schematic side elevation view of a spaced array of cylindrical magnets in an example magnetic connector;

FIG. 14 is a schematic side elevation view of the spaced array of cylindrical magnets of FIG. 13 aligned with a complementary spaced array of cylindrical magnets of a complementary magnetic connector;

FIG. 15 is a schematic side elevation view of another example spaced array of cylindrical magnets of an example magnetic connector;

FIG. 16 is a schematic side elevation view of the spaced array of cylindrical magnets of FIG. 15 aligned with a complementary spaced array of cylindrical magnets of a complementary magnetic connector;

FIG. 17 is a schematic side elevation view of the spaced array of cylindrical magnets of FIG. 15 in a misalignment position with respect to a complementary spaced array of cylindrical magnets of a complementary connector;

FIG. 18 is a perspective view of an alternative embodiment of electronic device incorporating a transmit antenna that produces an ultra short range wireless signal having a toroidal radiation pattern;

FIG. 19 is perspective view of a further alternative embodiment of system for ultra short range wireless interaction comprising two electronic devices having magnetic connectors;

FIG. 20 is a perspective view of the system of FIG. 19 in which the electronic devices have been physically connected to one another using magnetic connectors so that complementary antennas in the respective devices are automatically aligned for ultra short range wireless interaction;

FIG. 21 schematically depicts an alternative system for ultra short range wireless interaction in which each device has two antennas;

FIG. 22 schematically depicts an alternative system for ultra short range wireless interaction in which each device has only one magnetic connector; and

FIGS. 23 and 24 are perspective views of an alternative system for ultra short range wireless interaction between two devices showing alignment of different sets of wireless elements when the devices are in a side-to-side arrangement versus a face-to-face arrangement, respectively.

### DETAILED DESCRIPTION

In this disclosure, the terms “height,” “horizontal,” “vertical,” “top” and “bottom” should not be understood to necessarily imply any particular required orientation of a device or component during use. In this disclosure, the term “cylindrical magnet” should be understood to include cylindrical magnets whose heights are smaller than their radii, which magnets may alternatively be referred to as “disk magnets.” In this disclosure, the term “cylindrical magnet” should be understood to include hollow cylindrical magnets, including annular or tubular magnets. Any use of the term “exemplary” should not be understood to mean “preferred.”

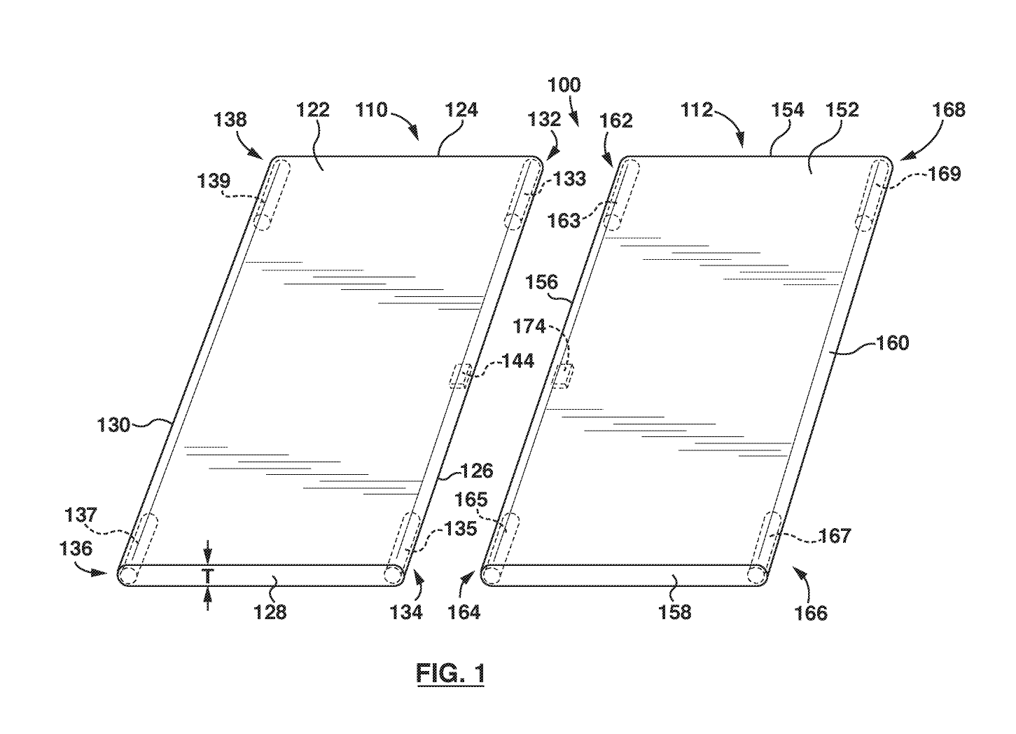

Referring to FIG. 1, an exemplary ultra short range wireless communication system 100 is illustrated. The system 100 includes a first electronic device 110 and a second electronic device 112. The devices 110, 112 may be any electronic devices that interact with one another wirelessly at ultra short range and provide complementary functions. For example, one device may be smartphone and the other a speaker. As further examples, one of the devices may be a smartphone and the other a viewing screen; both may be viewing screens; one device may be a viewing screen and the other a keyboard; one device may be a touchscreen enabled device and the other a router to communicate to the Internet; or one may be a camera and the other a smartphone to store images or video from the camera. In general, the electronic devices 110, 112 may be of the same or different types and may have the same or different form factors. Possible device types may include tablet computers, laptop computers, keyboards, speakers, printers, or scanners, among others. It will be appreciated that the exact function of the devices 110, 112 is not central and that other types of electronic devices besides the ones specifically enumerated above may be used.

As shown in FIG. 1, electronic device 110 has a housing 122 with a generally flat cuboid shape and a thickness T. The housing 122 (FIG. 1) may be made from a non-conductive material such as plastic. The housing 122 has four straight edges 124, 126, 128 and 130. In this embodiment, edges 124 and 128 are flat, and edges 126 and 130 are rounded. Edges 126 and 130 may accordingly be referred to as straight rounded edges. The rounding of edges 126, 130 may be for aesthetic, ergonomic, or functional reasons, or a combination of these. In the present embodiment, the straight rounded edges 126, 130 have a semi-circular profile or cross section. In other embodiments, the straight rounded edges of a device may have profiles of different shapes (e.g. semi-elliptical, parabolic, quarter-circular, quarter-elliptical, or otherwise). The straight rounded edges 126, 130 are elongate.

Four magnetic connectors 132, 134, 136 and 138 are disposed at the four corners of the device 110 respectively. In other embodiments, there may be fewer connectors per device (e.g., two rather than four), and the connectors may be placed elsewhere than the corners.

Each magnetic connector is designed to self-align and interconnect with a complementary magnetic connector (i.e. mating connector) when the two connectors are brought into proximity with one another. Each of the magnetic connectors 132, 134, 136 and 138 uses one or more magnets to achieve this self-aligning effect and to interconnect complementary magnetic connectors once aligned. The magnetic connectors may be as described in U.S. patent application Ser. No. 15/134,660 filed Apr. 21, 2016 or as described in International PCT publication WO 2015/070321, both of which are hereby incorporated by reference.

In the embodiment illustrated in FIG. 1, each magnetic connector 132, 134, 136 and 138 comprises a respective cylindrical magnetic element 133, 135, 137 and 139. A cylindrical magnetic element is either a single cylindrical magnet or multiple cylindrical magnets arranged coaxially. The cylindrical magnetic element produces the magnetic force that automatically aligns the connector with a complementary magnetic connector of another device when the connectors are brought into proximity with one another, and interconnects the magnetic connectors once aligned.

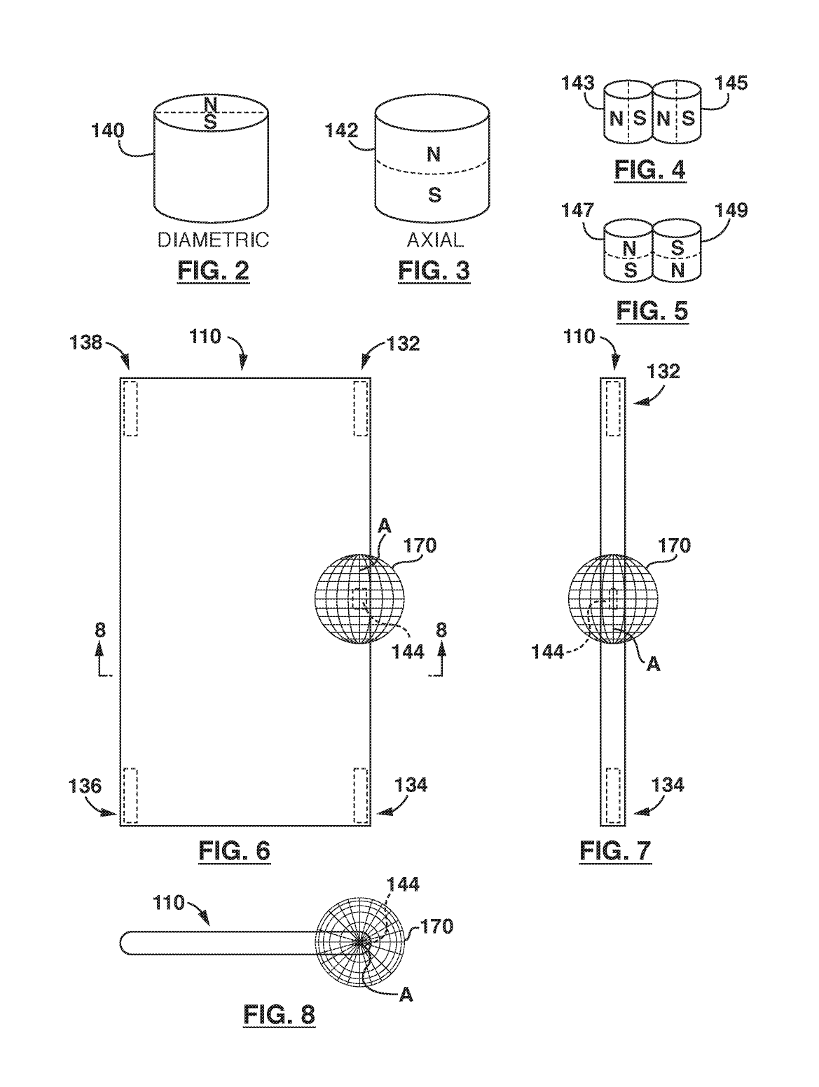

The cylindrical magnets comprising each cylindrical magnetic element may be diametric, axial or a combination of the two. As is known in the art, a diametric cylindrical magnet has a diametric magnetic orientation, like the example diametric cylindrical magnet 140 of FIG. 2, and an axial cylindrical magnet has an axial magnetic orientation, like the example axial cylindrical magnet 142 of FIG. 3. Generally, a diametric cylindrical magnet may provide a stronger attraction to a complementary diametric cylindrical magnet, while an axial cylindrical magnet may provide better longitudinal alignment with a complementary axial cylindrical magnet. Combining these magnet types in a single magnetic connector may provide a mixture of these benefits.

For clarity, and with reference to FIG. 4, two diametric cylindrical magnets 143 and 145 arranged side by side with parallel axes and opposite poles facing one another provide an example of two “complementary” diametric cylindrical magnets. Referring to FIG. 5, two axial cylindrical magnets 147 and 149 arranged side by side with parallel axes and opposing polarities (e.g. N pole of magnet 147 facing upwardly and N pole of magnet 149 facing downwardly) provide an example of two “complementary” axial magnets. It will be understood that these examples of complementary magnets are not exhaustive and that magnetic connectors may use other types of magnets (e.g. non-cylindrical magnets, such as spherical magnets or bar magnets).

Referring back to FIG. 1, the cylindrical magnet(s) comprising exemplary magnetic connectors 132, 134, 136 and 138 each has a diameter that is substantially equal to the thickness T of the device 110 or slightly smaller than thickness T, so that the cylindrical magnets will fit inside the housing 122. Depending upon a strength and/or magnetic orientation of the cylindrical magnet(s), this may promote a strong magnetic attraction force over at least a portion of the curved profile of the rounded edge 126.

Each magnetic connector 132, 134, 136 and 138 also comprises a mounting structure, which is not expressly depicted in FIG. 1. In this embodiment, the mounting structure is designed to hold the magnet(s) of each magnetic connector so that an axis of the cylindrical magnet (or of a coaxially arranged array of cylindrical magnets) is substantially parallel to the straight rounded edge at which the magnetic connector is disposed. Referring to connector 132 as an example, the mounting structure may mount the cylindrical magnet(s) of that connector so that an axis of the cylindrical magnet(s) is substantially parallel to straight rounded edge 126. The term “substantially parallel” means parallel or almost parallel.

The mounting structure may also be configured to mount the cylindrical magnet(s) of a magnetic connector so that an axis of the cylindrical magnet(s) is coaxial with an axis of the cylindrical magnet(s) of any other magnetic connector disposed along the same straight rounded edge. For example, the mounting structure of magnetic connector 132 may be configured to mount its cylindrical magnet(s) so that an axis of the cylindrical magnet(s) is coaxial with an axis of the cylindrical magnet(s) the of the other magnetic connector 134 along the same edge 126. This may facilitate a hinge-like pivoting of the electronic device 110 relative to another electronic device 112 whose edge 156 attached to edge 126 via magnetic connectors, as will be described.

The mounting structure may take various forms and/or may be effected in various ways. The mounting structure may for example be a framework, a cage, a partially or fully cylindrical receptacle, or an adhesive. The mounting structure may be attached to, or may form part of, the device housing 122. In some magnetic connector embodiments, the mounting structure may be designed to allow cylindrical or spherical magnet(s) comprising the connector to rotate with respect to the housing. For example, if magnetic connector 132 were to include a diametric cylindrical magnet, the mounting structure of that magnetic connector may allow that magnet to rotate on its axis with respect to the housing, e.g. so that the correct pole presents itself at the curved profile of the straight rounded edge 126 (with “correctness” possibly being determined by the polarity of the magnet of an approaching connector). In other magnetic connector embodiments, the mounting structure may be designed to fix cylindrical magnet(s) with respect to the housing (e.g. by way of adhesive or friction). For example, if magnetic connector 132 were to include an axial cylindrical magnet, the mounting structure may fix that magnet with respect to the housing.

In the illustrated embodiment of FIG. 1, one pair of magnetic connectors 132, 134 is disposed along straight rounded edge 126, and another pair of magnetic connectors 136, 138 is disposed along opposing straight rounded edge 130. Each pair of magnetic connectors 132, 134 and 136, 138 is spaced apart along its respective straight rounded edge 126 and 130. The spacing apart of a pair of magnetic connectors along a given straight rounded edge may help to promote axial alignment of the straight rounded edge with an edge of an adjacent electronic device having a pair of complementary magnetic connectors spaced apart by the same distance, upon interconnection of the pairs of magnetic connectors of the respective devices.

The first electronic device 110 of FIG. 1 also comprises an antenna 144, which is a form of wireless element. In this example, the antenna 144 is a transmit antenna suitable for transmitting an ultra short range wireless signal. An ultra short range wireless signal is a wireless signal having an effective range of a few millimeters to a few centimeters between complementary transmit and receive antennas.

Transmit antenna 144 may be one of various types, with the chosen antenna type possibly depending upon such factors as the desired effective range and radiation pattern of the wireless signal, the operative wireless protocol(s) being used for ultra short range wireless communication, and/or the frequency or frequencies at which the electronic device is to operate. The antenna may for example operate using a single frequency, a narrow band, or a wide band (e.g., the ultra-wide band of 3.1 to 10.6 Ghz). In some embodiments, antenna 144 may be an extremely-high frequency (e.g., 30-300 Ghz) antenna, e.g., as described in U.S. Patent Publication No. 2015/0065069, which is hereby incorporated by reference. In some embodiments, antenna 144 may be a monopole or dipole antenna. Physically, the antenna 144 may have a cuboid shape, as depicted in FIG. 1, but the shape may vary in other embodiments. In some embodiments, the antenna 144 may be a chip antenna (e.g., ceramic), e.g. having a footprint of only a few square millimeters. If the operative ultra short range wireless communication protocol is NFC, the wireless element may be an inductor (e.g. a wire coil). In an embodiment, the antenna may be configured to transmit/receive signals within a “near-field” distance. As such, the antenna may transmit/receive signals according to inductive coupling effects, e.g., as described in “TransferJet—Concept and Technology Rev. 1.5”. In this case, the “radiation field” is more properly referred to as “induction field.” For convenience, the term “radiation field” will be used in the subsequent description, with the understanding that the term may include induction fields in some embodiments.

The transmit antenna 144 may be an antenna is operable in either a transmit mode or a receive mode, which is presently operating in the former mode.

In the illustrated embodiment, the antenna 144 is disposed between the pair of magnetic connectors 132, 134 at the straight rounded edge 126 of housing 122. In alternative embodiments, the antenna 144 may be placed elsewhere, e.g. not between two magnetic connectors and/or not at an edge of the device. A number of alternative arrangements are described below.

The antenna 144 is fixed with respect to the housing 122, e.g. by being mounted to a circuit board (not depicted) comprising the electronic device 110. As such, the antenna 144 and the pair of magnetic connectors 132, 134 that is disposed long the same edge 126 are in fixed relation to one another.

At least the portion of the housing 122 around antenna 144 may be formed of a material that minimizes attenuation to wireless signals from antenna 100 (e.g., a plastic).

In the illustrated example, the antenna 144 is an omnidirectional antenna that emits radiation in a spherical pattern. FIGS. 6-8 depict the device 110 in front, side and cross-sectional view, respectively, of with the antenna 144 actively transmitting an ultra short range wireless signal. The cross-section of FIG. 8 is taken along line 8-8 of FIG. 6.

The spherical radiation pattern (or simply “sphere”) 170 depicted in FIGS. 6-8 represents the (ultra short) effective range of the wireless signal being transmitted by antenna 144. It will be appreciated that the wireless signal does not necessarily end abruptly at the periphery of sphere 170 but instead becomes too attenuated to be reliably received by a complementary receive antenna. Thus, in this disclosure, a receive antenna that is physically within the bounds of the notional sphere 170 should be understood as being able to reliably receive the wireless signal, whereas a receive antenna that is physically outside the bounds of the notional sphere 170 should be understood as not being able to reliably receive the signal. The size of the sphere 170, or more generally, the extent of the antenna's effective range, may be determined, at least in part, by a power (dBm) at which antenna 144 is operated, with sphere size generally increasing with transmit power. The radius of sphere 170 may for example extend one or two centimeters in the illustrated embodiment.

The spherical radiation pattern 170 may be considered to have radial symmetry about an axis of symmetry A that is substantially parallel to the straight rounded edge 126 at which the antenna 144 is disposed.

Referring back to FIG. 1, it will be appreciated that the first electronic device 110 may include other components, e.g. other transmit antennas, receive antennas, other wireless elements, or circuitry, which are omitted for the sake of clarity.

The second electronic device 112 of the system 100 illustrated in FIG. 1 is similar to the first electronic device 110 shown in that figure. The device 112 also has a housing 152 with a generally flat cuboid shape, which may be made from a non-conductive material such as plastic. The housing 122 has four straight edges 154, 156, 158 and 160, with edges 154 and 158 being flat and edges 156 and 160 being straight and rounded. Four magnetic connectors 162, 164, 166 and 168, each having a similar design to connectors 132, 134, 136 and 138 described above, are disposed at the four respective corners of the device 112. The two magnetic connectors 162 and 164 disposed along edge 156 are complementary to connectors 132 and 134, respectively.

The second electronic device 112 also has an antenna 174, which is a form of wireless element. In the present embodiment, antenna 174 is a receive antenna that is complementary to (i.e. suitable for receiving wireless signals from) transmit antenna 144, described above. The receive antenna may be an antenna is operable in either a transmit mode or a receive mode, which is presently operating in the latter mode. Antenna 174 is disposed at the edge 156 of the housing 152 closest to electronic device 110 in FIG. 1, in between the pair of magnetic connectors 162 and 164 and in fixed relation thereto.

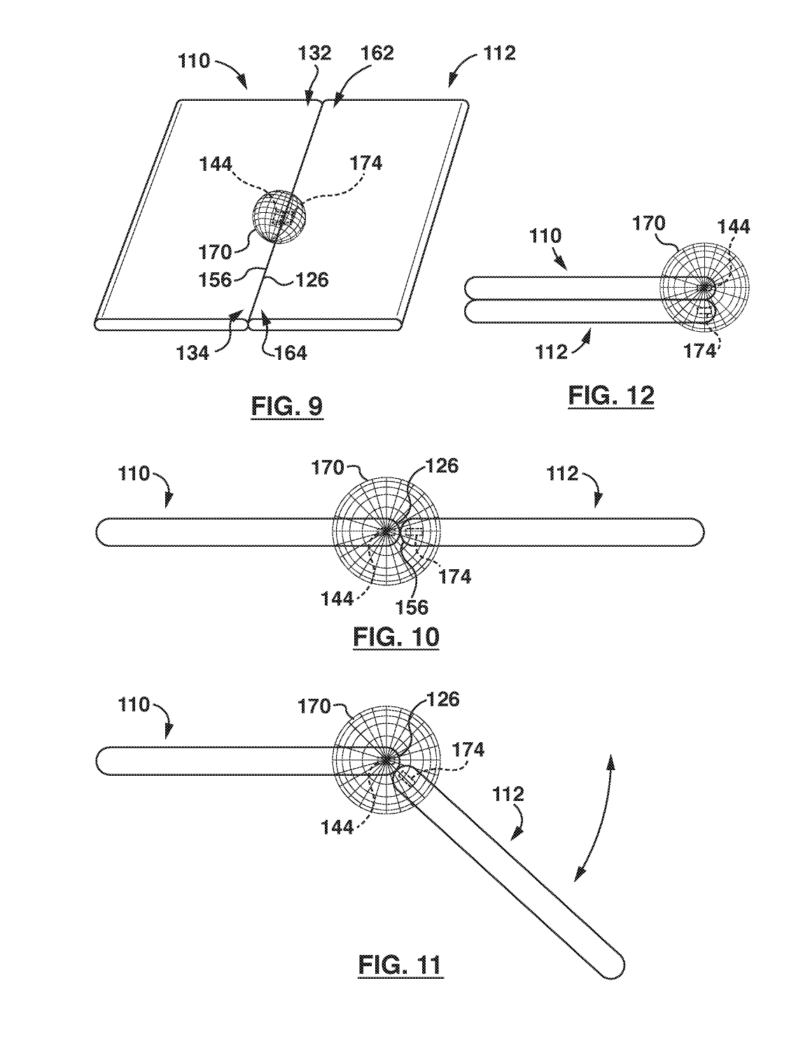

In operation, ultra short range wireless communication between electronic devices 110 and 112 of FIG. 1 may be facilitated by physically interconnecting the devices using the magnetic connectors. In particular, the straight rounded edge 126 of the first electronic device 110 may be brought into proximity with the straight rounded edge 156 of the second electronic device 112, until the two magnetic connectors 132, 134 of edge 126 self-align and interconnect with the two magnetic connectors 162, 164, respectively, of edge 156. The edges 126 and 156 of the respective devices 110 and 112 may appear to suddenly self-align and snap together. The alignment of the edges may be an axial alignment, longitudinal alignment, or both. Axial alignment causes straight edges 126, 156 to become substantially parallel with one another. Longitudinal alignment causes the lateral edges 126 and 156 to align lengthwise with respect to one another, e.g. so that top edges 124, 154 and bottom edges 128, 158 of the two respective devices 110, 112 are flush. In the result, the devices will be physically connected to one another along edges 126 and 156, as shown in FIGS. 9 and 10, which are perspective and bottom views, respectively, of the interconnected devices. The physical connection between the devices may be considered stable because if it persists despite the application of nominal external forces upon either or both of the interconnected electronic devices, such as forces associated with normal user handling of the devices during operation (e.g., to press buttons, or to pivot the devices relative to the hinge-like connecting edge).

Conveniently, the physical connection of the devices 110, 112 to one another by way of self-aligning magnetic connectors 132, 134, 162 and 164 automatically aligns the receive antenna 174 of electronic device 112 with the transmit antenna 144 of electronic device 110. This alignment is depicted in FIGS. 9 and 10 as the encompassing of receive antenna 174 within the spherical radiation pattern 170 of the transmit antenna 144. As a result of the alignment, the receive antenna 174 can reliably receive ultra short range wireless signals transmitted by the transmit antenna 144. The alignment may provide at least one of the following benefits: enhanced security through use of a wireless signal whose an ultra short range limits opportunities for eavesdropping; reduced interference with other components (e.g. transmit or receive antennas) within the same device and/or in nearby devices; and reduced power consumption in comparison to longer range antennas that might otherwise be required to transmit wireless signals between the devices.

The positioning or placement of antennas 144 and 174 within respective housings 126 and 156 may be such that, when the pairs of magnetic connectors 132, 134 and 162, 164 are interconnected to establish a stable physical connection between the electronic devices 110, 112, the antennas (wireless elements) 144, 174 will be separated by a predetermined distance that is in the ultra short range. Depending upon the embodiment or application in question, the distance may for example be less than 5 millimeters, less than 10 millimeters, less than 20 millimeters, less than 30 millimeters, less than 40 millimeters, or less than 50 millimeters.

The interconnected devices 110, 112 of FIGS. 9 and 10 may be considered to form a hinge. For example, referring to the bottom view of devices 110, 112 depicted in FIG. 11, it can be seen that electronic device 112 is pivotable about the straight rounded edge 126 of electronic device 110 in view of the physical connection between the devices along their respective edges 126, 156. This pivoting may permit the devices 110, 112 to achieve a stacked back-to-back arrangement, as shown in the bottom view of FIG. 12. Alternatively, the device 112 could be pivoted in the other direction until the two devices achieve a face-to-face stacked arrangement (not expressly depicted). Thus, either of the electronic devices 110, 112 of the present embodiment may be pivoted through an angle of approximately 360 degrees (e.g. starting in a stacked, face-to-face arrangement and ending in a stacked, back-to-back arrangement) without breaking its connection to the other device.

Throughout the pivoting depicted in FIGS. 11 and 12, the receive antenna 174 of electronic device 112 remains in alignment with the transmit antenna 144 of electronic device 110. This is represented in FIGS. 11 and 12 by the constant encompassing, by spherical radiation pattern 170, of receive antenna 174 at all stages of pivoting. Conveniently, ultra short range wireless communication may proceed uninterrupted between the devices, via the antennas 144, 174, even as the electronic devices 110, 112 are pivoted through various pivot positions relative to one another.

In the illustrated embodiment, the positioning and orientation of antenna 144 at or near device edge 126 may support continued antenna alignment during pivoting using minimal signal power. In particular, the antenna 144 may be positioned and oriented so that an axis of radial symmetry A of the radiation pattern 170 is at or near, and substantially parallel to, the straight rounded edge 126 about which the other device 112 pivots. As a result, the periphery (maximum effective range) of the transmit antenna's spherical radiation pattern 170 extends about the same distance from the surface of the rounded edge 126 over the entirety of the curved profile of that edge. This positioning and orientation of antenna 144 may accordingly allow receive antenna 174 to remain within the effective range of transmit antenna 144, regardless of a degree of pivoting of electronic device 112 relative to electronic device 110. This may allow the size of sphere 170 (i.e. transmit signal power) to be minimized.

In some embodiments, the axis of radial symmetry A of the radiation pattern 170 produced by transmit antenna 144 may be substantially coaxial with the cylindrical magnets of either or both of magnetic connectors 132 and 134 disposed along or proximate the same edge 126 of housing 122.

In some embodiments, the antenna may be placed as close to the edge of the device as possible, e.g. to maximize range while minimizing transmit power.

At least some of the above-described embodiments use self-aligning magnetic connectors comprising cylindrical magnets to facilitate alignment of transmit and receive antennas for ultra short range wireless communication. It will be appreciated that the tendency of such magnetic connectors to longitudinally self-align may be enhanced when: (a) each magnetic connector contains at least one cylindrical magnet of the axial type; or (b) each magnetic connector includes a plurality of cylindrical magnets (whether axial, diametric, or both) in a spaced array that destabilizes longitudinally misaligned positions, as described below.

In contrast, the tendency of such magnetic connectors to longitudinally self-align may be less strong when each magnetic connector includes only a single cylindrical magnet of the diametric type. In such embodiments, complementary magnetic connectors could conceivably achieve a stable connected position even when the connectors are slightly longitudinally misaligned or offset from one another. It is possible that such a connector offset could, in some embodiments, jeopardize the alignment of receive and transmit antennas for ultra short range wireless communication, e.g. if the effective range of a transmit antenna were so short that extremely precise antenna alignment is required. If so, it may be preferable or necessary to avoid using magnetic connectors have just a single diametric magnet in each connector or to slightly increase the effective range of the transmit antenna.

Conversely, some degree of longitudinal misalignment or offset of magnetic connectors may be tolerable in some embodiments. This may for example be the case when an effective range of the transmit antenna is sufficiently large to encompass the receive antenna even when magnetic connectors are slightly misaligned. Thus the choice of magnets, and their arrangement, within the magnetic connectors of a particular embodiment may be based, at least in part, upon the tolerance of the embodiment or application in question for slight antenna misalignment.

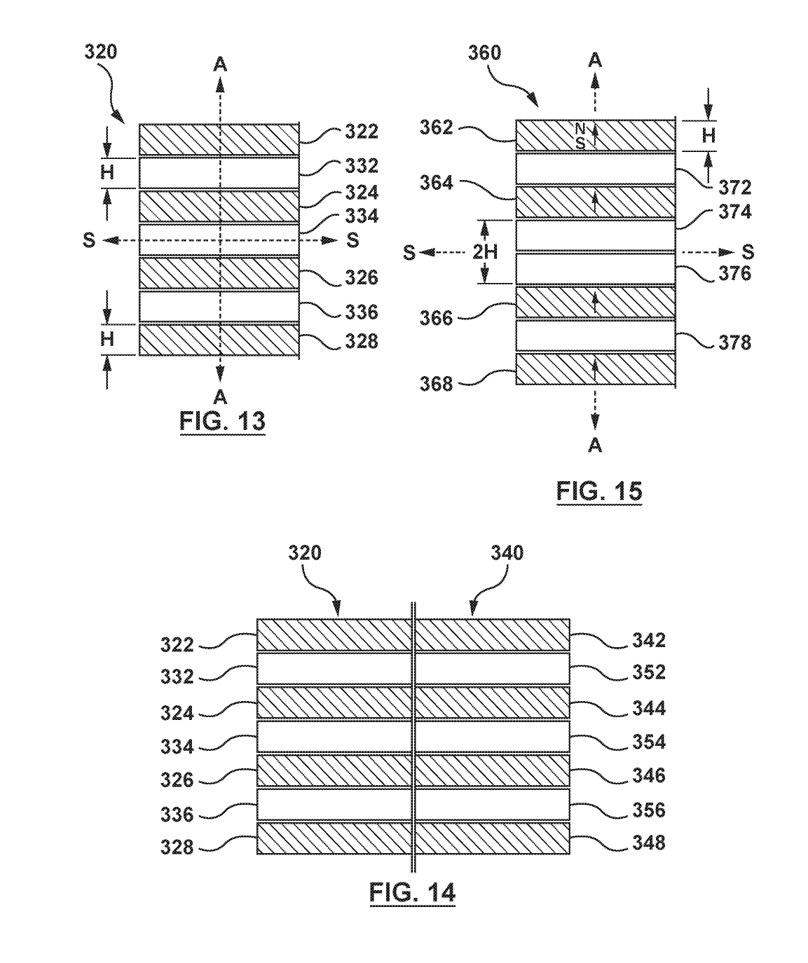

As noted above, each magnetic connector of the embodiment depicted in FIG. 1 may comprise a plurality or array of cylindrical magnets arranged coaxially. In such embodiments, the cylindrical magnets may be spaced apart into a spaced array. This is depicted in FIG. 13.

FIG. 13 is a side elevation view of one example cylindrical magnetic element 320 of a magnetic connector (connector not expressly shown). The cylindrical magnetic element 320 comprises four cylindrical magnets 322, 324, 326 and 328 of equal size and shape (thus having uniform heights H) arranged coaxially. The magnets may be axial cylindrical magnets. FIG. 13 (and subsequent figures) adopts a notation whereby the polarity of each magnet is shown with an arrow, with the head of the arrow pointing to the N pole of the magnet. The cylindrical magnetic element 320 further includes three uniform spacers 332, 334 and 336 between neighboring ones of the cylindrical magnets 322, 324, 326 and 328 respectively. Each spacer may be made from a non-magnetic and non-ferrous material, such as nylon, plastic, or rubber for example. The spacers may be shims.

In the illustrated embodiment, the height (i.e. thickness or longitudinal extent) of each spacer 332, 334 and 336 matches the height (i.e. thickness or longitudinal extent) of a cylindrical magnet, which is denoted H in FIG. 13. In other words, the spacing of the cylindrical magnets in the spaced array is regular: all neighboring magnets in the arrangement are spaced apart equally.

The cylindrical magnetic element 320 may be considered to provide a spaced array of cylindrical magnets that is longitudinally symmetric. The term “longitudinally symmetric” in this context means symmetric relative to a plane of symmetry S that transversely bisects cylindrical magnetic element 320 and to which longitudinal axis A of the cylindrical magnetic element 320 is normal.

FIG. 14 schematically depicts, in side elevation view, the cylindrical magnetic element 320 of FIG. 13 when connected with a complementary cylindrical magnetic element 340 of a complementary magnetic connector. In FIG. 14, each cylindrical magnet 322, 324, 326 and 328 comprising cylindrical magnetic element 320 is longitudinally aligned and magnetically interconnected with a respective complementary cylindrical magnet 342, 344, 346 and 348 comprising cylindrical magnetic element 340.

When a spaced array of cylindrical magnets comprising a connector self-aligns and connects with a complementary spaced array of cylindrical magnets of a complementary connector as shown in FIG. 14, the connectors will tend to be longitudinally stable with respect to one another. Application of a small longitudinal force upon one of the connectors will not tend to longitudinally displace the cylindrical magnetic elements 320, 340 from one another, particularly when at least one complementary pair of cylindrical magnets is of the axial type.

One way in which the longitudinal self-aligning effect may be enhanced may be to arrange the cylindrical magnets into a spaced array in which the spacing is irregular. This is illustrated in FIG. 15.

FIG. 15 is schematic depiction, in side elevation view, of an alternative cylindrical magnetic element 360 of another notional connector. Like cylindrical magnetic element 340 of FIG. 13, the cylindrical magnetic element 360 of FIG. 15 comprises four cylindrical magnets 362, 364, 366 and 368 arranged coaxially. The magnets are of equal size and shape and thus have uniform heights H. In this example, the magnets are axial magnets, each having the same polarity.

The cylindrical magnetic element 360 of FIG. 15 includes one spacer between each pair of neighboring cylindrical magnets, with the spacers having a uniform height H (thickness). An exception is that one additional spacer has been inserted between the middle two magnets 364, 366, thereby doubling the space between these two magnets in comparison to the space between the other neighboring magnets.

In view of the doubling of the space between magnets 364 and 366, the spacing of the cylindrical magnets in the arrangement of FIG. 15 is irregular, i.e. some neighboring magnets are spaced apart further than others. Note that, despite this irregularity, the spaced array of magnets of FIG. 15, like that of FIG. 13, is longitudinally symmetric, i.e. symmetric relative to a plane of symmetry S that transversely bisects cylindrical magnetic element 360 and to which longitudinal axis A of the cylindrical magnetic element 300 is normal.

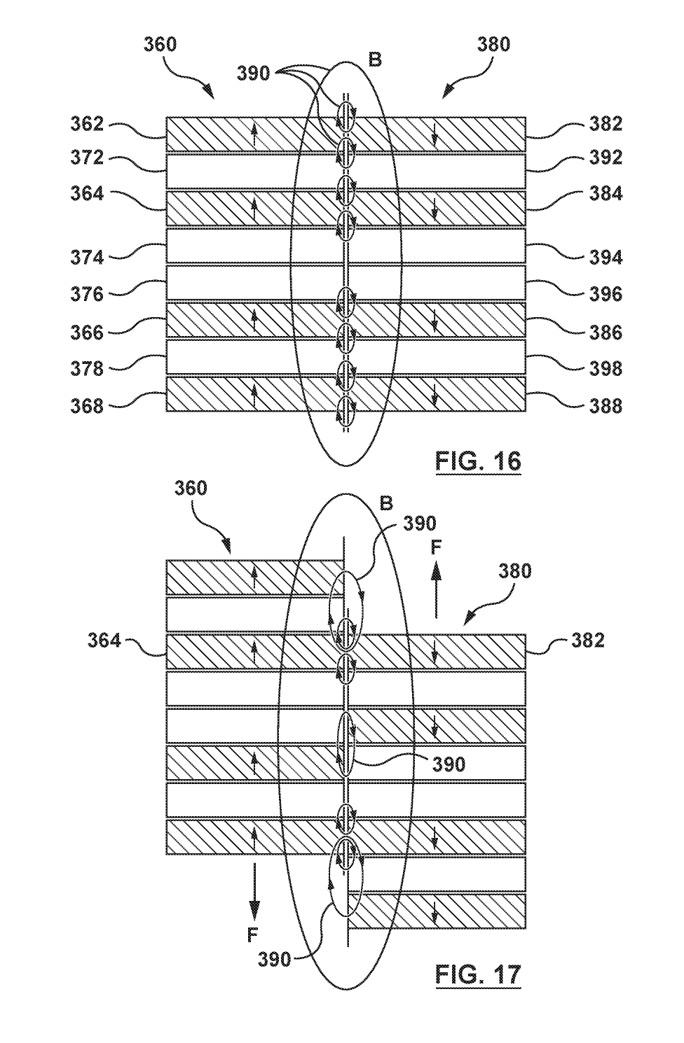

FIG. 16 schematically depicts, in side elevation view, the cylindrical magnetic element 360 of FIG. 15 longitudinally aligned and connected with a complementary cylindrical magnetic element 380 of another notional connector. In FIG. 16, each cylindrical magnet 362, 364, 366 and 368 comprising cylindrical magnetic element 360 is longitudinally aligned and magnetically interconnected with a respective complementary cylindrical magnet 382, 384, 386 and 388 comprising cylindrical magnetic element 380. Magnetic flux lines 390 are also depicted in FIG. 16.

As a consequence of doubling the space between magnets 364 and 366, when the connectors are misaligned, at most one-half of the cylindrical magnets of each connector (i.e. two magnets of four in this embodiment) will align with complementary magnets of the other connector. This is true regardless of the degree of longitudinal misalignment of the connectors, i.e. regardless of the degree of longitudinal misalignment of cylindrical magnetic elements 360 and 380.

For example, one possible longitudinal misalignment scenario is schematically depicted in FIG. 17. Example magnetic flux lines 390 are again shown. As can be seen, several magnetic flux lines have lengthened along an axis parallel to the connection surface (i.e. longitudinally) in relation to the longitudinally aligned scenario of FIG. 16. This lengthening of flux lines reflects the presence of opposing net magnetic forces F that tend to pull the cylindrical magnetic elements 360, 380, and thus their respective connectors, towards alignment in a direction parallel to the connection surface. In other words, the forces F destabilize the misaligned position of FIG. 17, reflecting an enhanced tendency of the connectors to longitudinally self-align.

The doubled spacing between cylindrical magnets need not be at the middle of the connector in order to provide the enhanced self-alignment benefits discussed above. The doubled spacing could instead be towards the top (e.g., between the first and second magnets), or towards the bottom (e.g., between the third and fourth magnets), of the connector.

An enhanced longitudinal self-alignment effect may also be achieved by adjusting a height (i.e. thickness or longitudinal extent) of one or more magnets instead of, or in addition to, adjusting the height of the spacers (if any).

Referring back to FIG. 1, it will be appreciated that the other magnetic connectors 136, 138 and 166, 168 may have a similar design to the magnetic connector 132, 134, 162 and 164, described above.

Various alternative embodiments are possible.

In one alternative, the wireless elements of an alternative embodiment may be longitudinal electric induction couplers, as described for example in “TransferJet—Concept and Technology Rev. 1.5” issued by the Transfer Jet Consortium, the contents of which are incorporated herein by reference. Ultra short range wireless communication may occur between such antennas in accordance with the protocol defined in the above-referenced document. The wireless communication may be considered to conform to the TransferJet™ protocol or a version thereof. In such embodiments, the radiation pattern that is produced may be referred to as an electric induction field. Conveniently, the use of electric field induction may improve the data transmission rate, e.g., to over 500 Mbit/s or higher.

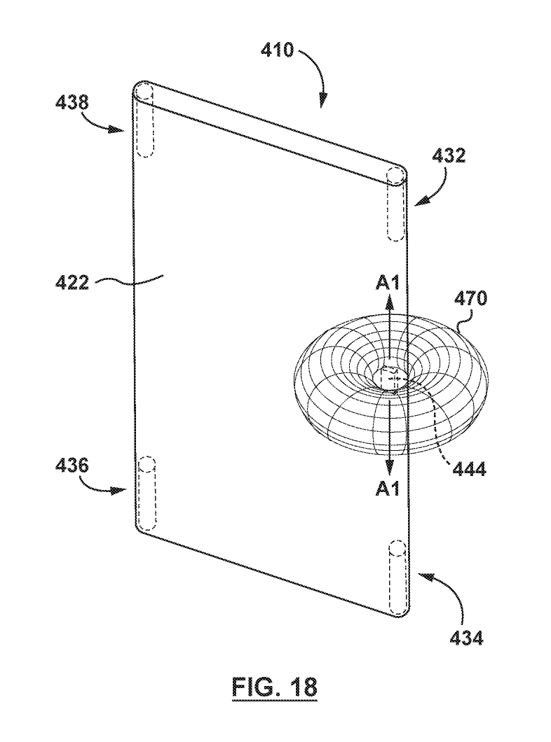

In another alternative, when the wireless element is a transmit antenna, the antenna may have a radiation pattern that is non-spherical. For example, an omnidirectional transmit antenna producing a toroidal (torus or doughnut shaped) radiation pattern may be used. This is illustrated in FIG. 18.

Referring to FIG. 18, an alternative embodiment of electronic device 410 is illustrated in perspective view. The electronic device 410 is in many respects similar to the electronic device 110 depicted in FIG. 1. The device 410 has a housing 422 with a flat cuboid shape having four magnetic connectors 432, 434, 436 and 438 disposed in its four corners respectively. The magnetic connectors may be similar to the four magnetic connectors 132, 134, 136 and 138 of device 110 described above. One pair of the magnetic connectors 432, 434 is spaced apart from one another and is disposed along a straight rounded edge 426 of the housing in fixed relation to an antenna 444. The antenna 444 (a form of wireless element) is disposed at or near the straight rounded edge 426, in between the pair of connectors 432, 434.

Antenna 444 is an omnidirectional antenna 444 having a toroidal radiation pattern 470 with an axis of radial symmetry A1. The antenna 444 may be oriented and positioned within the housing 422 so that this axis of radial symmetry A1 is parallel or substantially parallel to the edge 426 of the device and is disposed at or near the edge 426. This may permit the toroidal radiation pattern 470 to encompass a complementary antenna (or, more generally, a complementary wireless element) disposed at an edge of a counterpart device whose edge is magnetically connected to rounded edge 426 regardless of whether the devices are positioned back-to-back, face-to-face, or at an angle that is somewhere in between. The devices may accordingly engage in ultra short range wireless communication even as one is pivoted relative to the other in the manner of a hinge. In some embodiments, the axis of radial symmetry A1 of the transmit antenna 444 may be coaxial with cylindrical magnets comprising either or both of magnetic connectors 432 and 434.

In some embodiments, interconnected electronic devices may not be capable of or intended to pivot hinge-like relative to one another during use. In such embodiments, it may not be particularly advantageous for the transmit antenna to be oriented so that its radiation field's axis of radial symmetry is parallel to an edge of the electronic device.

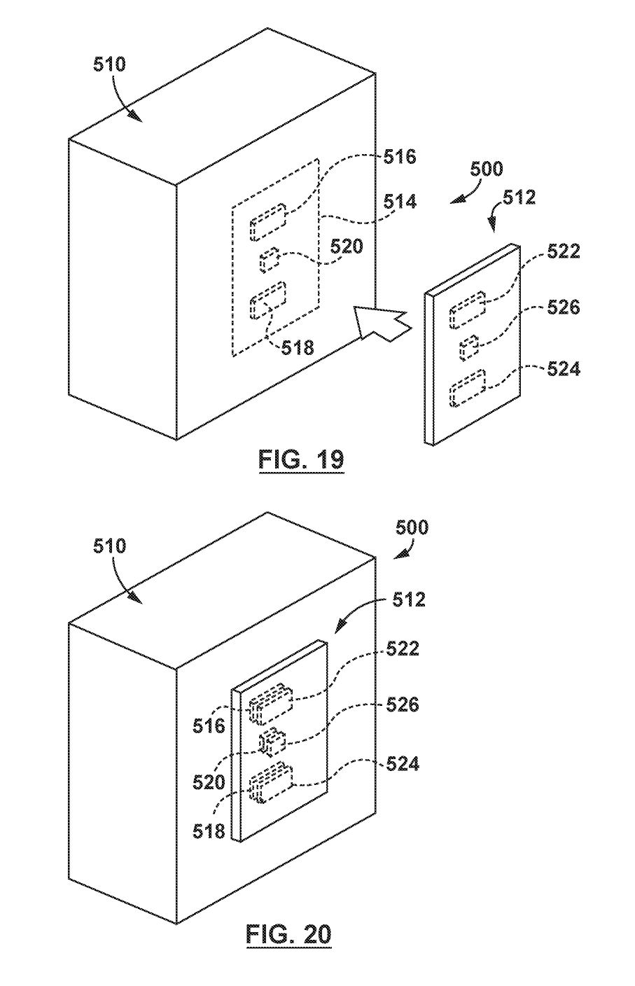

In some embodiments, one device may be mountable or attachable, via magnetic connectors, to another device that presents a mounting or attachment surface having complementary magnetic connectors. The surface could be flat or irregularly shaped and could be oriented vertically, horizontally, or at some other angle. A wireless element beneath or behind the attachment surface may be complementary to a wireless element within the attached device and may support ultra short range wireless interaction between the two devices via the wireless elements. This is illustrated in FIGS. 19 and 20.

Referring to those figures, an ultra short range wireless communication system 500 is shown in perspective view. The system 500 includes a first device 510 and a second device 512. The first device 510 may be large or immobile, such as a home appliance, a building structural element (e.g. a wall), a piece of furniture, or a vehicle dashboard. The second device 512 may be a portable electronic device.

The first device 510 defines an attachment surface 514 for magnetically aligning and attaching the second device 512. The attachment surface may or may not be marked as such and may or may not be discernible to the eye. In some embodiments, the attachment surface may be vertical (e.g. a wall); in others, it may be horizontal (e.g. a table top). The locations of the magnetic connectors 516, 518 and antenna 520 may or may not be apparent.

A pair of spaced apart magnetic connectors 516, 518 and an antenna 520 (a form of wireless element) may be disposed on, beneath or behind the attachment surface 514, in fixed relation to one another.

The second device 512 comprises a complementary pair of magnetic connectors 522, 524 and a complementary antenna (complementary wireless element) 526, also in fixed relation to one another, inside a device housing.

When the portable device 512 is brought into proximity with the device 510 as shown in FIG. 19, the magnetic connectors 522, 524 of the former device will self-align and interconnect with the complementary magnetic connectors 516, 518, respectively, of the latter device. The device 512 may appear to suddenly align with the attachment surface 514 just before it attaches itself thereto. The antennas 520 and 526 will automatically become aligned for ultra short range wireless communication therebetween by virtue of the interconnection. The resulting physically interconnected devices may appear as depicted in FIG. 20. The magnetic connectors may be sufficiently strong to support a weight of the portable electronic device 512, even if the attachment surface 514 is vertical.

In some embodiments, the portable device 512 may be configured to act as a control panel for device 510, using ultra short range wireless communication via antennas 520, 516 to, e.g., controlling an actuator of device 510 proximate the attachment surface (e.g. a door lock or light switch).

The devices described herein may be embodied in various other forms. In one example, a smartphone device may be magnetically coupled to a device that is a point-of-sale machine, a gas pump, or a vending machine, and ultra short range wireless communication may be used to effect a monetary transaction. In another example, a smartphone device may be magnetically coupled to a large-screen television, and ultra short range wireless communication may be used to transmit video data from the smartphone device to the television for display thereon.

The devices may have various other form factors, e.g., be embodied in a flash drive, a stylus, a wearable device, or otherwise.

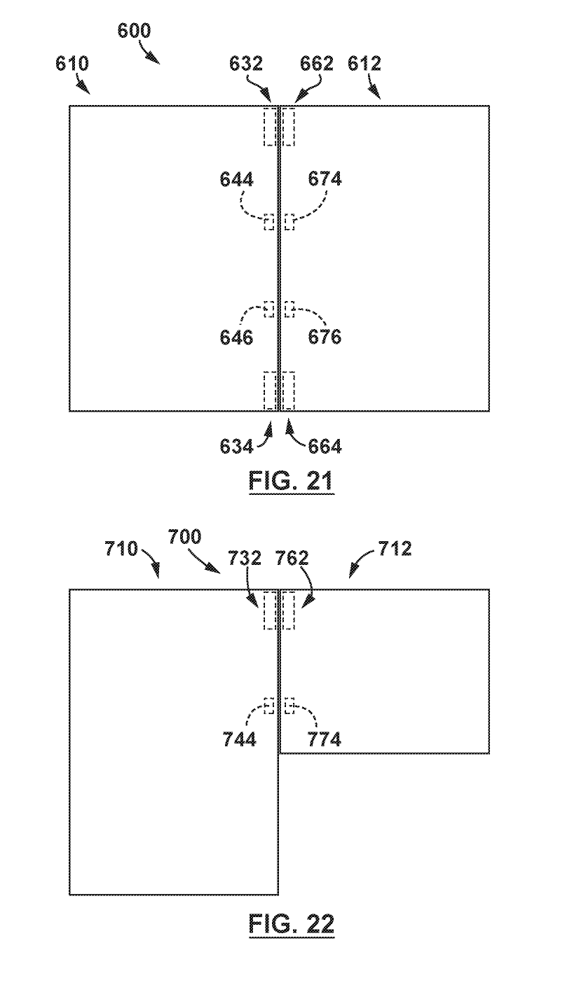

In some embodiments, each device may contain multiple wireless elements to wirelessly interact with the same device. This is schematically depicted in FIG. 21.

Referring to that figure, a system 600 for ultra short range wireless communication including two complementary devices 610, 612 is shown. The devices are physically coupled together using magnetic connectors 632, 634 and 662, 664. A pair of transmit antennas (a pair of wireless elements) 644, 646 is disposed along an edge of device 610 in fixed relation to the magnetic connectors 632, 634. Each antenna 644, 646 is spaced far enough apart from the other such that, when they each transmit an ultra short range wireless signal, or if one transmits such a signal while the other is receiving for full-duplex communication, the signals do not interfere with one another or only do so minimally. A pair of receive antennas 674, 676 is similarly disposed along an edge of the other device 612. When the devices 610, 612 are magnetically coupled to one another using the connectors, complementary antennas are aligned with one another for ultra short range wireless communication. Transmitting data through both sets of antennas simultaneously may provide for increased data throughput between the devices 619 and 612.

In some embodiments, it may be possible to achieve wireless element alignment for ultra short range wireless interaction between devices using only one magnetic connector per device. This is schematically depicted in FIG. 22.

Referring to that figure, a system 700 for ultra short range wireless communication including two complementary devices 710, 712, having different form factors, is shown. The devices are physically coupled together using complementary magnetic connectors 732, 762. The magnetic connectors may be elongate or may use multiple magnets, e.g. as shown in FIGS. 16 and 17 above, to promote an enhanced tendency for longitudinal and axial self-alignment of the devices 710, 712, given the absence of any other magnetic connectors. An antenna 744 (a form of wireless element) is disposed along an edge of device 710 in fixed relation to the magnetic connectors 732. A complementary antenna 774 is similarly disposed along an edge of the other device. When the devices 710, 712 are magnetically coupled to one another using the connectors, complementary antennas 744, 774 are aligned with one another for ultra short range wireless communication.

Use of only a single magnetic connector per device as in FIG. 22 may represent a compromise. On one hand, fewer magnetic connectors may free up real estate within devices for other components and may reduce magnetic connector costs. On the other hand, the physical interconnection between devices 710, 712 may be less stable than that between two devices interconnected by spaced apart pairs of magnetic connectors, e.g. as in FIG. 21. This reduced stability may necessitate the use of higher signal power (larger radiation patterns) for ultra short range wireless communication between antennas 744, 744, to compensate for possible antenna misalignment, e.g. from a slight axial misalignment of the edges of the devices 710, 712. Placement of the antennas as close as possible to the magnetic connectors in single-connector device embodiments may reduce the degree of antenna misalignment that may be experienced between devices.

It will be appreciated that, to the extent that a magnetic connector is situated at a straight rounded edge of a device, that rounded edge need not necessarily have a semi-circular profile or cross-sectional shape. In some embodiments, the profile of a straight rounded edge of a device may be otherwise partly circular. In other embodiments, the straight rounded edge may not have a partly circular cross-sectional profile at all, but may instead have another rounded cross-sectional shape, such as semi-elliptical, partly elliptical, parabolic, partly parabolic or blunt. The profile may determine or limit the angle through which the device may be swung while maintaining a magnetic connector in a connected state.

At least some of the magnetic connector embodiments discussed above employ a cylindrical magnet that is fixedly or rotatably held in a housing of a device, so that the axis of the cylindrical magnet is substantially parallel, and in fixed relation, to a straight rounded device edge. It will be appreciated that, in some embodiments, the cylindrical magnet of a connector may occupy a hollow at a device edge and may be movable within the hollow between a stowed position and a deployed position. In such cases, the axis of the cylindrical magnet may be movable relative to the straight rounded device edge. It will be appreciated that a magnetic connector employing such a movable magnet may nevertheless be considered to be in fixed relation to the housing of the device and/or to any fixed device component, such as an antenna, because the overall connector position remains unchanged despite any possible movement of the substituent magnet during use.

In some embodiments, the wireless element could be a directional antenna mechanically coupled to a magnetic connector comprised of a rotatable diametric magnet, configured so that, as the magnetic connector rotates, the antenna rotates to follow.

Any of the cylindrical magnets contemplated herein may be electromagnets.

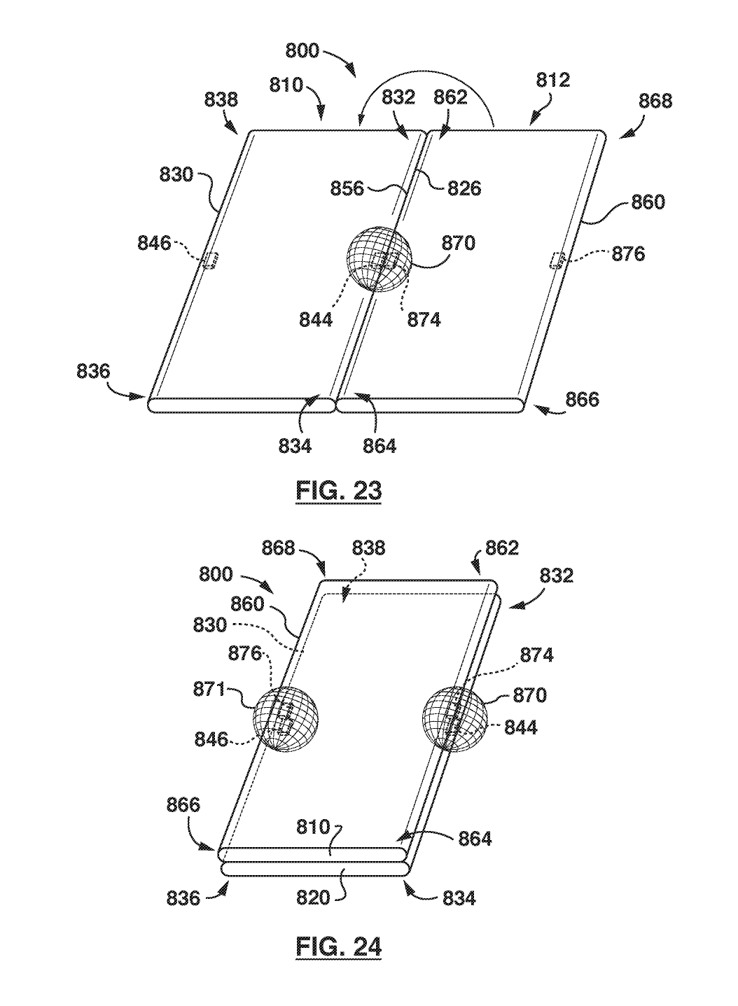

In some embodiments, each electronic device may contain multiple wireless elements and multiple magnetic connectors. Different subsets of the magnetic connectors may be mutually interconnectable in order to physically interconnect the devices in different relative positions, with the number of aligned wireless elements possibly being dependent upon the relative positions of the devices. This is depicted in FIGS. 23 and 24.

Referring to FIGS. 23 and 24, a system 800 is depicted. The system includes two electronic devices 810 and 812, which are analogous in most respects to respective electronic devices 110, 112 of FIGS. 9-12, described above. A difference is that each electronic device 810, 812 of FIGS. 23 and 24 not only has a first antenna 844, 874 disposed along a first straight rounded edge 826, 856, but also has a second antenna 846, 876 disposed along an opposing straight rounded edge 830, 860, respectively. All of the antennas are forms of wireless elements.

In operation, ultra short range wireless interaction between electronic devices 810 and 812 of FIG. 23 may initially be facilitated by physically interconnecting the edges 826 and 856 of the devices using the magnetic connectors, at a first time t1. In particular, the two magnetic connectors 832, 834 of edge 826 may be interconnected with the two magnetic connectors 862, 864, respectively, of edge 856, to yield a stable side-by-side physical connection between devices 810, 812, as shown in FIG. 23. Conveniently, receive antenna 874 of electronic device 812 automatically aligns with the transmit antenna 844 of electronic device 810.

At a subsequent time t2, electronic device 812 may be pivoted about the straight rounded edge 826 of electronic device 810 until the devices 810, 812 achieve a stacked face-to-face (or back-to-back) arrangement, as shown in FIG. 24. Throughout the pivoting, the receive antenna 874 of electronic device 812 remains in alignment with the transmit antenna 844 of electronic device 810. This is represented in FIGS. 23 and 24 by the constant encompassing, by spherical radiation pattern 870 produced by transmit antenna 844, of receive antenna 874 at all stages of pivoting.

Once the devices are stacked as in FIG. 24, the magnetic connectors 836, 838 disposed along edge 830 of device 810 align and interconnect with magnetic connectors 866, 868, respectively, disposed along edge 860 of device 812. This new interconnection lends further stability to the system 800, possibly with the result that each device 810, 812 can now carry the weight of the other when the connected devices are handled.

In the arrangement of FIG. 24, the second antenna 846 in device 810 has become aligned with the second antenna 876 of device 812, as depicted by the encompassing of receive antenna 876 by radiation pattern 871 produced by transmit antenna 846. The alignment of this second pair of wireless elements may automatically trigger a dynamic reconfiguration of the wireless communications between devices 810 and 812, to benefit from additional data throughput provided by the newly aligned antennas. Thus, a user may conveniently control a degree of wireless interaction between devices merely by rearranging the devices into different stable positions using the magnetic connectors.

If the devices are returned to the position of FIG. 23, or are placed into an analogous side-by-side position but with the edges 830, 860 being connected rather than edges 826, 856, a complementary dynamic reconfiguration of wireless communications between devices 810, 812, to use only the wireless elements that have remained in alignment, may be performed.

Notably, the distance between antennas 844, 846 and between antennas 874, 876 may be chosen to limit interference between them when the antennas are active. The precise distance required to achieve that result may vary with such parameters as antenna size, transmit power, and transmit frequency or frequencies.

Many of the above embodiments specifically describe wireless elements that are antennas. It will be appreciated that wireless elements are not necessarily antennas in all embodiments. As noted above, in some embodiments, the wireless elements may be longitudinal electric induction couplers. In some embodiments, wireless elements may be coils, such as planar coils, e.g. as may be used for power transfer, e.g. accordingly to the Qi™ inductive power standard.

It will be appreciated that, in any of the above embodiments in which one electronic device comprises a wireless element that is a transmit antenna and the other electronic device comprises a wireless element that is a receive antenna, the transmit antenna and the receive antenna could be swapped in alternative embodiment.

The following clauses describe additional aspects of the present disclosure.

Clause 1. An electronic device comprising: a wireless element; and a pair of magnetic connectors spaced apart from one another and in fixed relation to the wireless element, the pair of magnetic connectors being configured to self-align with, and interconnect with, a complementary pair of magnetic connectors of an other electronic device and to thereby align the wireless element with a complementary wireless element of the other electronic device for ultra short range wireless interaction between the electronic devices via the aligned wireless elements.

Clause 2. The electronic device of clause 1 further comprising a housing having an edge, wherein the pair of magnetic connectors and the wireless element are disposed along the edge of the housing.

Clause 3. The electronic device of clause 2 wherein the edge is a straight rounded edge.

Clause 4. The electronic device of clause 3 wherein the pair of magnetic connectors is configured to cause the straight rounded edge of the electronic device to physically connect with an edge of the other electronic device upon interconnection of the pairs of magnetic connectors, the other electronic device being pivotable about the straight rounded edge, in a hinge-like manner, without breaking the physical connection between the edges of the electronic devices, the wireless element being configured to remain aligned with the complementary wireless element of the other electronic device for ultra short range wireless interaction regardless of a current pivot position of the other electronic device about the straight rounded edge.

Clause 5. The electronic device of clause 4 wherein the wireless element is a transmit antenna operable to produce an ultra short range wireless signal having a radiation pattern with an axis of radial symmetry that is substantially parallel to the straight rounded edge about which the other electronic device is pivotable.

Clause 6. The electronic device of clause 5 wherein pair of magnetic connectors comprises cylindrical magnets and wherein the axis of radial symmetry of the radiation pattern producible by the transmit antenna is substantially coaxial with the cylindrical magnets of the pair of magnetic connectors.

Clause 7. The electronic device of clause 1 wherein the wireless element is a longitudinal electric induction coupler.

Clause 8. The electronic device of clause 7 wherein the ultra short range wireless interaction comprises wireless communication conforming to the TransferJet™ protocol.

Clause 9. The electronic device of clause 1 wherein the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 20 millimeters.

Clause 10. The electronic device of clause 1 wherein the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 40 millimeters.

Clause 11. A system comprising: a first electronic device including: a first wireless element; and at least one magnetic connector in fixed relation to the first wireless element; and a second electronic device including: a second wireless element; and at least one complementary magnetic connector in fixed relation with the second wireless element, wherein the at least one magnetic connector of the first electronic device and the at least one complementary magnetic connector of the second electronic device are configured to self-align with, and interconnect with, one another and to thereby align the first and second wireless elements for ultra short range wireless interaction between the first electronic device and the second electronic device via the aligned wireless elements.

Clause 12. The system of clause 11 wherein the wireless interaction comprises wireless communication.

Clause 13. The system of clause 11 wherein the wireless interaction comprises wireless power transfer.

Clause 14. The system of clause 11 wherein the at least one magnetic connector of the first electronic device comprises a spaced apart pair of magnetic connectors and wherein the at least one complementary magnetic connector of the second electronic device comprises a similarly spaced apart pair of complementary magnetic connectors that is complementary to the pair of magnetic connectors of the first electronic device.

Clause 15. An electronic device comprising: a wireless element; a magnetic connector in fixed relation to the wireless element, the magnetic connector being configured to self-align with, and interconnect with, a complementary magnetic connector of an other electronic device and to thereby align the wireless element with a complementary wireless element of the other electronic device for ultra short range wireless interaction between the electronic devices via the aligned wireless elements.

Clause 16. The electronic device of clause 15 wherein each of the magnetic connector and the complementary magnetic connector has an elongate shape.

Clause 17. The electronic device of clause 15 wherein each of the magnetic connector and the complementary magnetic connector comprises a spaced array of magnets having an irregular spacing.

Clause 18. A system comprising: a plurality of electronic devices, each electronic device comprising a plurality of wireless elements and a plurality of magnetic connectors in fixed relation to the wireless elements, wherein different subsets of the magnetic connectors are mutually interconnectable in order to stably physically interconnect the electronic devices in different relative positions, and wherein the number of wireless elements that align for ultra short range wireless interaction between devices via the aligned wireless elements is dependent upon the relative positions of the devices.

Other modifications may be made within the scope of the following claims.

What is claimed is:

1. An electronic device comprising:
a wireless element;
a pair of magnetic connectors spaced apart from one another and in fixed relation to the wireless element, the pair of magnetic connectors being configured to self-align with, and interconnect with, a complementary pair of magnetic connectors of an other electronic device and to thereby align the wireless element with a complementary wireless element of the other electronic device for ultra short range wireless interaction between the electronic devices via the aligned wireless elements.

2. The electronic device of claim 1 further comprising a housing having an edge, wherein the pair of magnetic connectors and the wireless element are disposed along the edge of the housing.

3. The electronic device of claim 2 wherein the wireless element is disposed between the pair of magnetic connectors at the edge of the housing.

4. The electronic device of claim 2 wherein the edge is a straight rounded edge.

5. The electronic device of claim 4 wherein the pair of magnetic connectors is configured to cause the straight rounded edge of the electronic device to physically connect with an edge of the other electronic device upon interconnection of the pairs of magnetic connectors, the other electronic device being pivotable about the straight rounded edge, in a hinge-like manner, without breaking the physical connection between the edges of the electronic devices, the wireless element being configured to remain aligned with the complementary wireless element of the other electronic device for ultra short range wireless interaction regardless of a current pivot position of the other electronic device about the straight rounded edge.

6. The electronic device of claim 5 wherein the wireless element is a first wireless element, wherein the pair of magnetic connectors is a first pair of magnetic connectors, and wherein the electronic device further comprises a second wireless element in fixed relation to a second pair of magnetic connectors, the second pair of magnetic connectors configured to connect with a complementary second pair of magnetic connectors in the other electronic device when the other electronic device has been pivoted about the straight rounded edge into a face-to-face or back to back arrangement of the electronic devices, so as to provide a stable physical connection between the electronic devices in which the second wireless element is aligned with a complementary second wireless element in the other electronic device for ultra short range wireless interaction therebetween.

7. The electronic device of claim 6 wherein the second wireless element and the additional magnetic connector are disposed along an opposing edge of the housing.

8. The electronic device of claim 5 wherein the wireless element is a transmit antenna operable to produce an ultra short range wireless signal having a radiation pattern with an axis of radial symmetry that is substantially parallel to the straight rounded edge about which the other electronic device is pivotable.

9. The electronic device of claim 1 further comprising an attachment surface to which the other electronic device is stably attachable using the pair of magnetic connectors, wherein the wireless element is situated on, beneath or behind the attachment surface.

10. The electronic device of claim 9 wherein the transmit antenna is an omnidirectional antenna having a spherical radiation pattern.

11. The electronic device of claim 9 wherein the transmit antenna is an omnidirectional antenna having a torus radiation pattern.

12. The electronic device of claim 1 wherein the wireless element is a longitudinal electric induction coupler.

13. The electronic device of claim 1 wherein the wireless element is a coil for effecting wireless power transfer.

14. The electronic device of claim 1 wherein the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 5 millimeters.

15. The electronic device of claim 1 wherein the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 10 millimeters.

16. The electronic device of claim 1 wherein the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 30 millimeters.

17. The electronic device of claim 1 wherein the wireless element is disposed within the electronic device so that, when the pairs of magnetic connectors are interconnected to establish a stable physical connection between the electronic devices, the wireless element of the electronic device and the complementary wireless element of the other electronic device will be separated by a distance of less than 50 millimeters.

18. A method of facilitating ultra short range wireless interaction between two electronic devices, the method comprising:
bringing a first electronic device into proximity with a second electronic device until a spaced apart pair of magnetic connectors in the first electronic device self-aligns and interconnects with a spaced apart pair of magnetic connectors in the second electronic device, the self-alignment and interconnection of the pairs of magnetic connectors automatically causing a wireless element in the first electronic device and a complementary wireless element in the second electronic device to align for ultra short range wireless interaction; and
effecting the ultra short range wireless interaction between the wireless element of the first electronic device and the aligned complementary wireless element of the second device.

19. The method of claim 18 wherein the interconnecting of the pairs of magnetic connectors establishes a hinge-like physical interconnection of the two electronic devices that permits pivoting of one of the electronic devices relative to the other while maintaining the alignment of the wireless element and the complementary wireless element for ultra short range wireless interaction.

20. The method of claim 18 wherein each of the two electronic devices has an edge within which one of the pairs of magnetic connectors is disposed and wherein the interconnecting of the pairs of magnetic connectors longitudinally and axially aligns the edges of the electronic devices.

21. An electronic device comprising:
a wireless element;
a magnetic connector in fixed relation to the wireless element, the magnetic connector being configured to self-align with, and interconnect with, a complementary magnetic connector of an other electronic device and to thereby align the wireless element with a complementary wireless element of the other electronic device for ultra short range wireless interaction between the electronic devices via the aligned wireless elements.

22. An electronic device comprising:
a plurality of wireless elements; and
a plurality of magnetic connectors in fixed relation to the wireless elements, the magnetic connectors being configured to self-align with, and interconnect with, complementary magnetic connectors of an other electronic device to physically interconnect the electronic device with the other electronic device in any one of a plurality of stable relative positions of the electronic devices, wherein the number of wireless elements that align with complementary wireless elements in the other electronic device for ultra short range wireless interaction is specific to the relative position of the electronic devices.
